(19) United States
(12) Patent Application Publication
(10) Pub. No.: US 2026/0229441 A1
(43) Pub. Date: Aug. 6, 2026

(54) Insulator, Insulator-Equipped Charged Particle Gun, Insulator-Equipped Charged Particle Beam Device, and Insulator Manufacturing Method

(71) Applicant: Hitachi High-Tech Corporation, Minato-ku, Tokyo (JP)

(72) Inventors: Shuhei ISHIKAWA, Minato-ku, Tokyo (JP); Takashi DOI, Tokyo (JP); Hiroshi MORITA, Tokyo (JP); Daigo KOMESU, Tokyo (JP); Yasushi YAMANO, Tsukuba-shi (JP); Hiromitsu NOGI, Tsukuba-shi (JP); Soichi KATAGIRI, Tsukuba-shi (JP)

(21) Appl. No.: 19/149,594

(22) PCT Filed: Feb. 24, 2023
(86) PCT No.: PCT/JP2023/006621

§ 371 Date: Jul. 21, 2025

(51) Int. Cl. H01J 29/06

(52) U.S. Cl. CPC H01J 29/06

(57) ABSTRACT

The present invention provides an insulator and the like capable of withstanding an acceleration voltage of 100,000 electron volts or more without using an acceleration tube having a multi-stage structure. An insulator 1 comprises: an insulation member 10; a cathode and an anode that are provided to the insulation member 10; and a metal film 13 that is provided to the surface of the insulation member 10. The metal film 13 has one or a plurality of metal films 13b with a surface resistance of 10¹² Ω/sq to 10¹⁵ Ω/sq between the cathode and the anode.

### DESCRIPTION

### Technical Field

The present disclosure relates to an insulator, a charged particle gun including an insulator, a charged particle beam apparatus including an insulator, and a method for producing an insulator.

### Background Art

An electron beam or an ion beam used in an electron microscope, an ion beam processing apparatus, an electron beam accelerator provided in a synchrotron radiation facility, or the like has a structure in which the electron beam or the ion beam is accelerated by applying energy to electrons or ions by a DC high voltage particularly in initial acceleration. In particular, the electron microscope has a structure in which an electron source is applied with a negative high voltage with respect to a ground potential, and electrons are accelerated by a potential difference between the electron source and the ground potential. The energy of the electron beam in this case is several hundred electron volts to several hundred thousand electron volts.

In these apparatuses, an electron source or an ion source is placed under a high voltage, and generated electrons or ions are accelerated using a potential difference toward an anode (in a case of an electron beam or a negative ion beam) or a cathode (in the case of a positive ion beam) having a potential close to zero, thereby obtaining an electron beam or an ion beam.

At this time, when an electron source or an ion source maintained at a high voltage of 100,000 electron volts or more is used, a tube called an “acceleration tube” connecting to the ground potential is formed in most cases. In many cases, the acceleration tube also serves as a vacuum vessel and serves as a passage for the electron beam or ion beam, and needs to be made of a nonconductor or a high-resistance material so as to maintain a high voltage without discharge.

When a high voltage is applied to electrodes provided on such a high-resistance material, a phenomenon called “surface flashover discharge” occurs, in which discharge occurs along a surface of the high-resistance material between the sandwiched electrodes. A model of the surface flashover discharge is illustrated in FIG. 11. When a negative voltage is applied to a cathode 1111 to increase a voltage, a negative electric field is concentrated at a triple point where the cathode 1111, vacuum, and an insulator 1110 as a dielectric intersect, and when a limit is exceeded, field emission electrons are emitted into the vacuum. The emitted electrons collide with the insulator 1110 in a process of moving toward an anode 1112. If there is one or more secondary electrons generated at this time, the number of electrons increases like an avalanche and flows into the anode 1112. In this state, since the cathode 1111 and the anode 1112 are short-circuited, discharge occurs. Therefore, in order to prevent the surface flashover discharge, it is necessary to reduce the voltage or increase a distance between the cathode and anode to alleviate the electric field concentration.

Next, a structure of an electron gun in the related art will be described with reference to FIG. 12. An electron beam extracted and emitted from an electron source 1201 by a potential difference with an extraction electrode 1202 is accelerated between the electron source 1201 and an anode 1212 at a ground potential, and passes through an acceleration tube 1215. The acceleration tube 1215 is provided with a large number of intermediate electrodes 1208-1 to 1208-4. The intermediate electrodes 1208-1 to 1208-4 are maintained at approximately equal potentials from a potential close to the extraction electrode 1202 toward the ground potential by using resistors 1209-1 to 1209-4, and the resistors 1209-1 to 1209-4 form the acceleration tube 1215 having a multi-stage structure. Such a multi-stage structure is adopted in order to maintain a uniform potential difference between a control electrode 1207 and each of the intermediate electrodes 1208-1 to 1208-3 and to alleviate electric field concentration. Insulators 1210-1 to 1210-4 are incorporated to insulate the control electrode 1207, the intermediate electrodes 1208-1 to 1208-3, and the anode 1212 from each other. As a result, there is an essential problem that the apparatus becomes large.

PTLs 1 and 2 disclose the above-described acceleration tube having a multi-stage structure.

Citation List Patent Literature PTL 1: JPS60-262339A PTL 2: JPH03-84839A Summary of Invention Technical Problem The electron microscopes include a transmission electron microscope (generally referred to as TEM) and a scanning electron microscope (generally referred to as SEM). Of the TEM and SEM, since an acceleration voltage in the SEM is limited to about 30,000 electron volts and it is not necessary to provide the above-described acceleration tube, a lightweight and small electron gun which does not require the acceleration tube is used. Therefore, it is possible to reduce a size and weight of the entire apparatus and to reduce cost, and therefore, the SEM is widely used compared with TEM.

The SEM is responsible for shape measurement of a semiconductor pattern in inspection of a semiconductor producing process, and is an important key apparatus for quality control. With the progress of high integration of semiconductors, a device structure becomes three-dimensional, and there is an increasing demand for measuring a shape of a finer and deeper hole bottom. For this purpose, it is necessary to further increase an accelerating voltage, and a region where an acceleration tube of about 100,000 electron volts is to be introduced is reached.

An object of the present disclosure is to provide an insulator capable of withstanding an acceleration voltage of 100,000 electron volts or more without using an acceleration tube having a multi-stage structure, a charged particle gun including an insulator, a charged particle beam apparatus including an insulator, and a method for producing an insulator.

### Solution to Problem

An insulator according to the present disclosure includes: an insulation member; a first electrode and a second electrode that are provided on the insulation member; and a metal film that is provided on a surface of the insulation member, in which the metal film has one or more regions with surface resistance of 10¹² Ω/sq to 10¹⁵ Ω/sq between the first electrode and the second electrode.

A charged particle gun according to the present disclosure includes the insulator described above.

A charged particle beam apparatus according to the present disclosure includes the insulator described above.

A method for producing an insulator according to the present disclosure includes: preparing an insulation member; forming one or more grooves on an outer circumferential surface of the insulation member; and forming a metal film on the outer circumferential surface on which the groove is formed, and providing one or more regions having surface resistance of 10¹² Ω/sq to 10¹⁵ Ω/sq on a side wall surface that is a sloped surface constituting the groove.

### Advantageous Effects of Invention

According to the present disclosure, it is possible to provide an insulator capable of withstanding an acceleration voltage of 100,000 electron volts or more without using an acceleration tube having a multi-stage structure, a charged particle gun including an insulator, a charged particle beam apparatus including an insulator, and a method for producing an insulator.

Other technical problems and novel features will become apparent from description of the present specification and the accompanying drawings.

### BRIEF DESCRIPTION OF DRAWINGS

FIG. 1 is a cross-sectional view illustrating a structure of an insulator 1 according to Embodiment 1.

FIG. 2 is a graph illustrating a relationship between a thickness and surface resistance of titanium nitride.

FIG. 3 is a partially enlarged view of a groove cross section of the insulator 1 according to Embodiment 1.

FIG. 4 is a cross-sectional view illustrating a structure of an insulator 2 according to Embodiment 2.

FIG. 5 illustrates a structure of an electron gun 500 according to Embodiment 3.

FIG. 6 illustrates a structure of a charged particle beam apparatus 600 according to Embodiment 4.

FIG. 7 illustrates an insulator 701 according to a first modification.

FIG. 8 illustrates an insulator 801 according to a second modification.

FIG. 9 illustrates an insulator 901 according to a third modification.

FIG. 10 illustrates an insulator 1001 according to a fourth modification.

FIG. 11 illustrates a model of surface flashover discharge.

FIG. 12 illustrates a structure of an electron gun in the related art.

### DESCRIPTION OF EMBODIMENTS

In the following embodiments, when necessary for convenience, the description will be made by being divided into a plurality of sections or embodiments, but unless otherwise stated, they are not unrelated to each other, and one has a relation with all or a part of modifications, details, supplementary explanations, and the like of the other.

In the following embodiments, when referring to the number of elements (including the number, numerical values, amounts, ranges, or the like) or the like, the number of elements is not limited to a specific number, and may be the specific number or more or the specific number or less, unless otherwise specified or except a case where the number is apparently limited to a specific number in principle.

Further, in the following embodiments, it is needless to mention that components (also including element steps and the like) thereof are not necessarily essential unless otherwise specified or unless clearly considered to be essential in principle.

Similarly, in the following embodiments, when a shape, a positional relation, or the like of a component or the like is referred to, the shape or the like is substantially approximate or similar to the shape or the like unless otherwise specified or clearly considered otherwise in principle. The same applies to the above-described numerical values and ranges.

In all drawings for describing the embodiments, the same members are denoted by the same reference numerals in principle, and repeated description thereof will be omitted.

### Embodiment 1

### (Structure of Insulator 1)

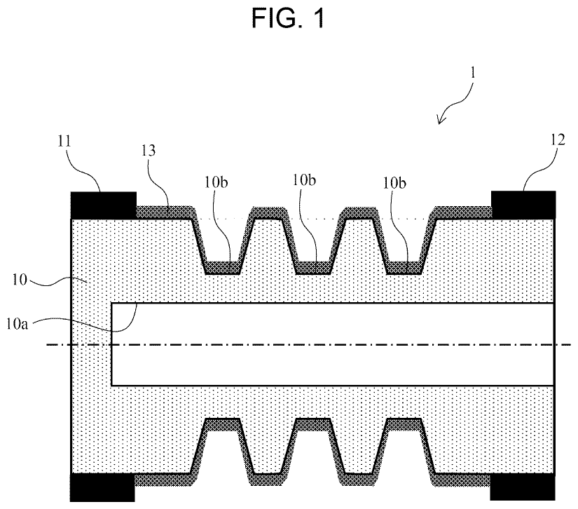

FIG. 1 illustrates the structure of the insulator 1 according to Embodiment 1. The insulator 1 includes an insulation member 10 having a substantially cylindrical shape, a cathode 11 (first electrode) and an anode 12 (second electrode) provided on the insulation member 10, and a metal film 13 provided on a surface (outer circumferential surface) of the insulation member 10. The metal film 13 has a plurality of annular regions having surface resistance of 10¹² Ω/sq to 10¹⁵ Ω/sq between the cathode 11 and the anode 12. Details will be described below.

The insulation member 10 is, for example, alumina (Al₂O₃). A secondary electron yield of alumina is about 7 to 8 at maximum. The insulation member 10 has a hollow 10a. A plurality of annular grooves 10b are formed on the outer circumferential surface of the insulation member 10 in a circumferential direction of the insulation member 10. The metal film 13 having a secondary electron yield lower than that of the insulation member 10 is provided on the outer circumferential surface of the insulation member 10 on which the plurality of grooves 10b are formed. The metal film 13 is, for example, titanium nitride (TiN). A secondary electron yield of the titanium nitride is 2 to 3. It is known that an electron avalanche phenomenon can be alleviated by lowering the secondary electron yield.

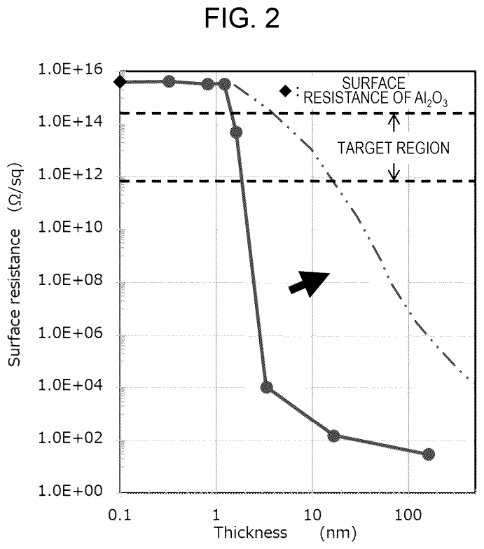

However, since the titanium nitride is a conductive material, surface resistance changes according to a thickness. The graph illustrated in FIG. 2 illustrates a relationship between a thickness and surface resistance of titanium nitride. From this graph, when the thickness of the titanium nitride is greater than 3 nm, the surface resistance becomes 10⁴ Ω/sq or less, which is a region that can be considered substantially a conductor. However, when the thickness of the titanium nitride is 1 nm to 3 nm, the titanium nitride is not a continuous film but an island-shaped region that can be considered discontinuous semiconductive, and a change in thickness of 0.1 nm results in an unstable state in which the surface resistance changes by several orders of magnitude. Meanwhile, when the thickness of the titanium nitride is 0 to 1 nm, the titanium nitride exhibits surface resistance equivalent to that of the alumina and becomes an insulating region.

Here, when a voltage of 100,000 electron volts is applied to the cathode 11, it is necessary to prevent a current value from several nA to 1 μA or less in order to avoid heat generation due to Joule heat caused by power of a power supply and a current flowing between the cathode and anode. Therefore, the surface resistance of the metal film 13 needs to be controlled to about 10¹² Ω/sq to 10¹⁵ Ω/sq. The thickness of the titanium nitride corresponding to a width of the surface resistance (target region in FIG. 2) is required to have very strict accuracy of 1.5 nm to 2.0 nm.

### (Method for Forming Metal Film 13)

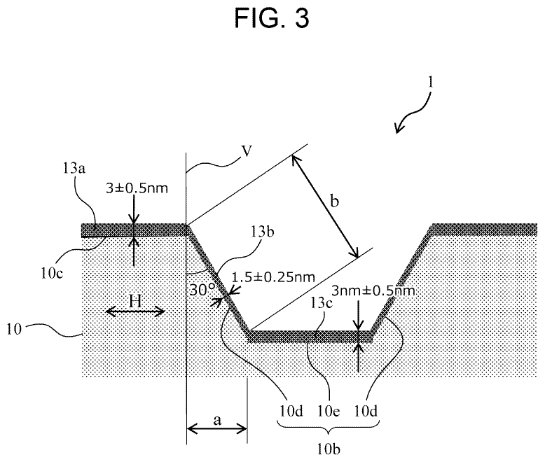

In the present embodiment, the following method is used to achieve film formation with the above accuracy. The method for forming the metal film 13 will be described with reference to FIG. 3. FIG. 3 is an enlarged view of a part of a groove cross section of the insulator 1 according to Embodiment 1.

The groove 10b is formed on a surface 10c of the insulation member 10. The groove 10b includes two sloped surfaces 10d and a bottom surface 10e sandwiched between the two sloped surfaces 10d. The sloped surface 10d is formed with an inclination of 30° (hereinafter, this angle is referred to as an angle of the sloped surface 10d) with respect to a perpendicular V to the surface 10c. The metal film 13 of titanium nitride is formed on the outer circumferential surface of the insulation member 10 on which the groove 10b is formed by, for example, a DC magnetron sputtering method. In the DC magnetron sputtering method, the film formation proceeds by causing highly directional particles to be incident perpendicularly on the outer circumferential surface of the insulation member 10. Here, a metal film formed on the surface 10c is a metal film 13a (second region), a metal film formed on the sloped surface 10d is a metal film 13b (first region), and a metal film formed on the bottom surface 10e is a metal film 13c (second region).

By the DC magnetron sputtering method, the film (metal film 13b) having a volume corresponding to a length a in a direction H along the surface 10c of the sloped surface 10d is formed on the sloped surface 10d having a length b. Therefore, a thickness of the metal film 13b on the sloped surface 10d is a/b of a thickness of the metal film 13a on the surface 10c. For example, as illustrated in FIG. 3, when the angle of the sloped surface 10d is 30°, if the metal film 13a of 3 nm is formed on the surface 10c, the metal film 13b of 1.5 nm is automatically formed on the sloped surface 10d. At this time, if a variation in a deposition thickness of the metal film 13a on the surface 10c is ±0.5 nm, a variation in a deposition thickness of the metal film 13b on the sloped surface 10d is reduced to ±0.25 nm. As described above, the film forming method has an advantage that the thickness of the metal film 13b on the sloped surface 10d can be highly accurate.

Further, since the thickness of the metal film 13a formed on the surface 10c is 3 nm, the metal film 13a is substantially a conductive film. Therefore, when a voltage is applied to the cathode 11, the titanium nitride film (metal film 13a) formed on the surface 10c of the insulation member 10 electrically connected to the cathode 11 has a potential equal to that of the cathode 11. Since the metal film 13b formed on the sloped surface 10d electrically connected to the metal film 13a has high surface resistance, a potential of the metal film 13b greatly drops from the potential of the cathode 11. The thickness of the titanium nitride film (metal film 13c) on the bottom surface 10e electrically connected to the metal film 13b is 3 nm, and therefore has a potential equal to the potential drop. Since a phenomenon in which the voltage drops stepwise is repeated from the cathode 11 to the anode 12, the potential on the outer circumferential surface of the insulator 1 becomes uniform in a stepwise manner. Accordingly, the insulator 1 has an advantage that the insulator 1 does not require use of an acceleration tube having a multi-stage configuration in the related art and can achieve a similar effect as a resistor implemented by the acceleration tube in the related art without using a resistor.

In the present embodiment, the angle of the sloped surface 10d is 30°, but it is obvious that an effect can be achieved even if the angle of the sloped surface 10d is any angle up to about 0° to 45°. Although the thickness of the titanium nitride film (metal films 13a and 13c) formed on the front surface 10c and the bottom surface 10e is set to 3 nm, the thickness may be set in the range of approximately 2 to 10 nm, and the angle of the sloped surface 10d may be appropriately selected so that surface resistance of the metal film 13b formed on the sloped surface 10d becomes desired surface resistance. In addition, although the example in which the number of the grooves 10b is three (see FIG. 1) is illustrated, the number of the grooves 10b is not limited, and may be two or less, or four or more.

In the present embodiment, the titanium nitride (TiN) having a lower secondary electron yield than alumina is used as a material for the metal film 13, but chromium (Cr), chromium oxide (Cr₂O₃), or the like may be used.

Further, by providing R at a corner of a shape of an end portion of the groove 10b (for example, a corner connecting the surface 10c and the sloped surface 10d or a corner connecting the sloped surface 10d and the bottom surface 10e) to moderate a change in thickness, electric field concentration occurring at the corner may be alleviated.

### (Method for Producing Insulator 1)

Here, a method for producing the insulator 1 will be described.

The method for producing the insulator 1 includes:
preparing the insulation member 10 having a substantially columnar shape;
forming one or more grooves 10b on the outer circumferential surface of the insulation member 10; and
forming the metal film 13 on the outer circumferential surface on which the grooves 10b are formed by using the above-described film forming method, and providing the metal film 13b with surface resistance of 10¹² Ω/sq to 10¹⁵ Ω/sq on the sloped surface 10d constituting the groove 10b.

### (Effects of Embodiment 1)

In Embodiment 1, by forming one or more grooves 10b on the outer circumferential surface of the insulation member 10 and forming the metal film 13 on the outer circumferential surface of the insulation member 10 on which the groove 10b is formed by the highly directional film forming method, the metal film 13b with the surface resistance of 10¹² Ω/sq to 10¹⁵ Ω/sq can be formed on the sloped surface 10d of the groove 10b. Accordingly, it is possible to obtain the insulator 1 capable of withstanding an acceleration voltage of 100,000 electron volts or more.

In Embodiment 1, by forming one or more grooves 10b on the outer circumferential surface of the insulation member 10 and forming the metal film 13 on the outer circumferential surface of the insulation member 10 on which the groove 10b is formed by the highly directional film forming method, the metal films 13a and 13b having different surface resistances can be alternately formed. Accordingly, a similar effect as that of the resistor implemented by the acceleration tube in the related art can be achieved without a resistor.

### Embodiment 2

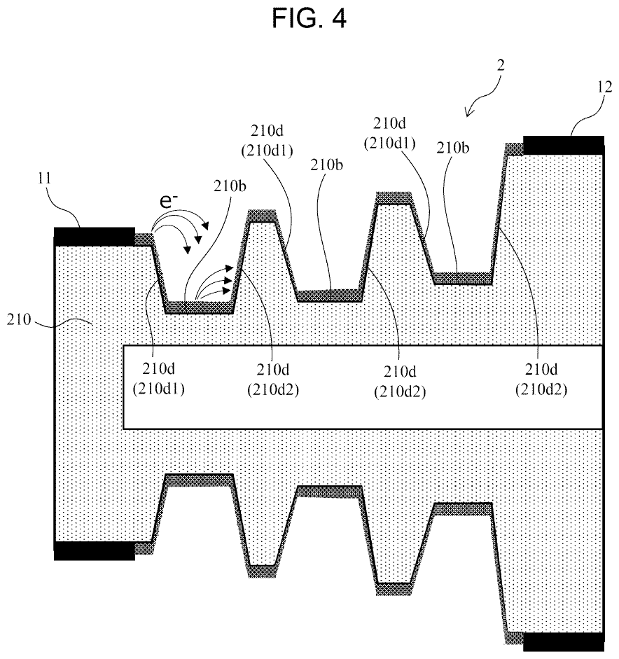

FIG. 4 illustrates a structure of an insulator 2 according to Embodiment 2. Since the secondary electron yield of the titanium nitride used in the insulator 1 according to Embodiment 1 is lower than the secondary electron yield of the alumina, a probability of surface flashover discharge decreases. However, in Embodiment 1, since a maximum value of the secondary electron yield is 1 or more, the electron avalanche cannot be completely eliminated. Therefore, in Embodiment 2, a groove 210b that gradually becomes higher from the cathode 11 toward the anode 12 is formed on an outer circumferential surface of an insulation member 210. A sloped surface 210d2 of the groove 210b on an anode 12 side is higher than a sloped surface 210d1 on a cathode 11 side. With such a configuration, a small amount of secondary electrons (e) collide with the sloped surface 210d of the groove 210b and are attenuated, so that the number of electrons reaching the anode 12 can be efficiently reduced.

Although the sloped surface of the groove 210b is gradually raised from the cathode 11 toward the anode 12 in Embodiment 2 described above, the sloped surface may not be gradually raised as long as the sloped surface 210d2 of one groove 210b on the anode 12 side selected from a plurality of grooves 210b is higher than the sloped surface 210d1 of the groove 210b on the cathode 11 side.

### Embodiment 3

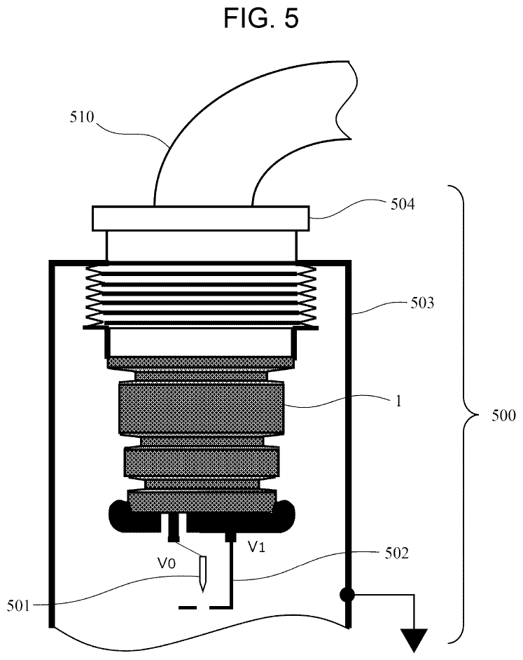

FIG. 5 illustrates a structure of an electron gun 500 according to Embodiment 3. The electron gun 500 (charged particle gun) according to Embodiment 3 includes the insulator 1 according to Embodiment 1. The electron gun 500 may include the insulator 2 according to Embodiment 2. The electron gun 500 includes the insulator 1, an electron source 501 (charged particle source), an extraction electrode 502, an electron gun column 503, and a high-voltage connector 504. A cable 510 is connected to the high-voltage connector 504.

The electron source 501 and the extraction electrode 502 are connected to the cathode 11 of the insulator 1, and a ground potential is connected to the anode 12. In the present embodiment, the electron source 501 is described as a cold cathode electron source, but the electron source 501 may be another type such as a Schottky electron source. A negative voltage of V0, which is an acceleration voltage, is applied to the electron source 501, and a voltage several kilovolts lower than V0 is applied to the extraction electrode 502 at a tip end of the electron source 501, which generates a strong electric field. An electron beam extracted from the electron source 501 is emitted downward in the drawing and enters an optical system (not illustrated).

As described in Embodiment 1, the plurality of grooves 10b are formed on the outer circumferential surface of the insulator 1, and the titanium nitride film is formed on the outer circumferential surface on which the plurality of grooves 10b are formed by the DC magnetron sputtering method. The angle of the sloped surface 10d of the groove 10b and the thickness are similar as those described in Embodiment 1.

Since the electron source 501 needs to operate in ultra-high vacuum, various components of the electron gun 500 are implemented inside the electron gun column 503. The electron gun column 503 is mostly made of stainless steel. In order to set an inside of the electron gun column 503 to an ultra-high vacuum, it is necessary to evacuate air, which is an atmospheric pressure at the beginning of start-up, by a vacuum exhaust pump, and to bake the entire electron gun column 503 at 200° C. or higher to reduce gas molecules emitted from a stainless steel wall surface. At this time, the insulator 1 is also exposed to a high temperature. At this time, metal atoms on a surface of the insulator 1 tend to diffuse into the insulator, and care is to be taken. This is because when a metal element diffuses into the insulator 1, surface resistance of the surface may vary to a lower side. The titanium nitride used in the insulator 1 has a diffusion barrier effect, and has an advantage that an effect of reducing such a surface resistance variation.

After baking is completed and the entire electron gun 500 returns to room temperature, a high-voltage power supply and the electron gun 500 are connected via the cable 510 and the high-voltage connector 504. A voltage to be applied is supplied from a high-voltage power supply (not illustrated) on an atmosphere side (outside the electron gun column 503) through the cable 510. The acceleration voltage V0 of the high-voltage power supply is 100,000 electron volts, and the electron gun 500 according to the present embodiment can be applied to a scanning electron microscope (SEM) or a transmission electron microscope (TEM). Although not described in detail, it is obvious that the invention can also be applied to a charged particle beam apparatus using an ion beam only by inverting positive and negative of the acceleration voltage.

### Embodiment 4

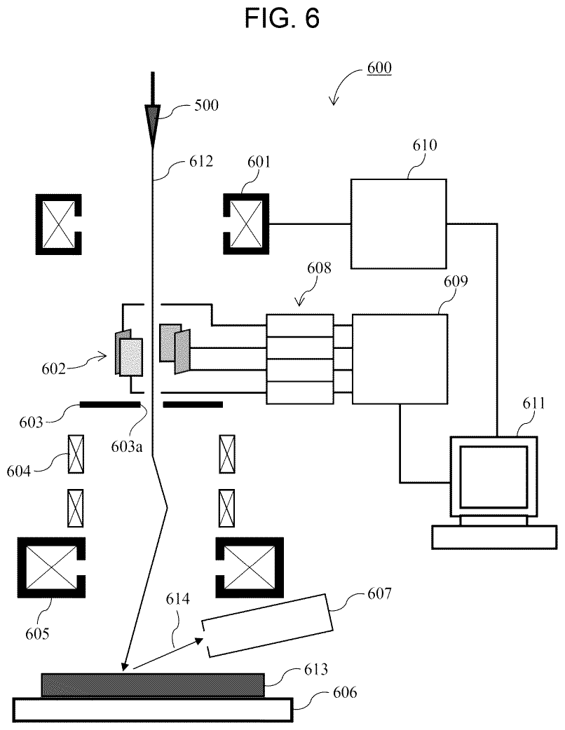

FIG. 6 illustrates a structure of a charged particle beam apparatus 600 according to Embodiment 4. The charged particle beam apparatus 600 according to Embodiment 4 includes the electron gun 500 according to Embodiment 3, a convergence lens 601, a blanking deflector 602, an aperture plate 603, an image shift deflector 604, an objective lens 605, a stage 606, a detector 607, a blanking voltage application device 608, a blanking voltage control device 609, a convergence lens control device 610, and a computer system 611.

An electron beam (primary beam) 612 emitted from the electron gun 500 passes through an aperture hole 603a of the aperture plate 603 due to a converging action of a magnetic field of the convergence lens 601. The electron beam 612 that passes through the aperture hole 603a is used to scan a sample 613 placed on the stage 606 by an electric field or magnetic field of the image shift deflector 604, and is converged on the sample 613 by a converging action of a magnetic field of the objective lens 605. Secondary electrons 614 generated from the sample 613 by irradiation with the electron beam 612 are detected by the detector 607. Accordingly, an enlarged image of a scanning region of the electron beam 612 on the sample 613 is obtained.

### (Modification)

The invention is not limited to the above-described embodiments and includes various modifications. For example, the above-described embodiments have been described in detail to facilitate understanding of the invention, and the invention is not necessarily limited to those including all the configurations described above. A part of a configuration of a certain embodiment can be replaced with a configuration of another embodiment, and a configuration of another embodiment can also be added to a configuration of a certain embodiment. In addition, another configuration can be added to, deleted from, or replaced with a part of a configuration of each embodiment.

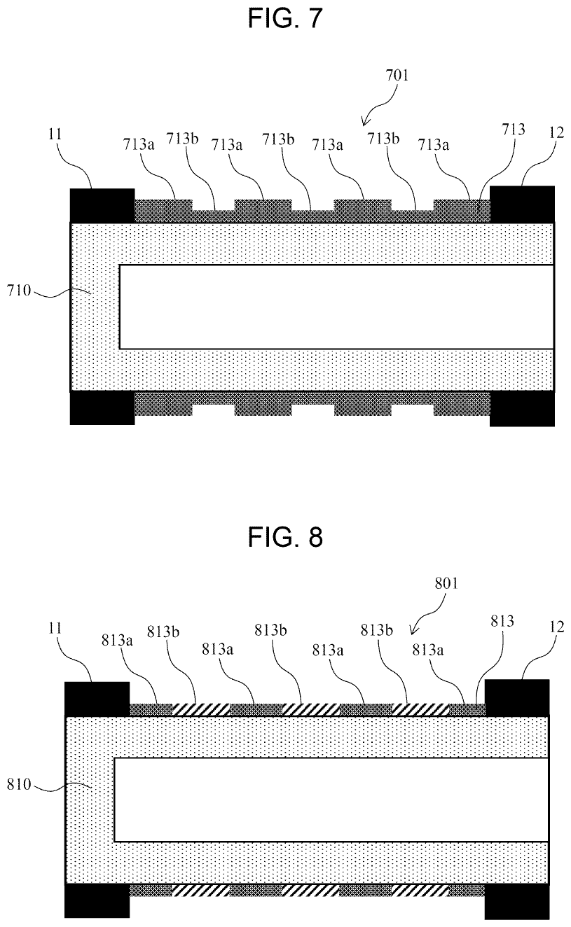

For example, FIG. 7 is a diagram illustrating an insulator 701 according to a first modification. Similarly to the insulator 1 according to Embodiment 1, the insulator 701 according to the first modification includes an insulation member 710, the cathode 11, the anode 12, and a metal film 713 formed on an outer circumferential surface of the insulation member 710. No groove is formed on the outer circumferential surface of the insulator 701 according to the first modification. In the first modification, a region 713a having a large thickness and a region 713b having a small thickness of the metal film 713 are alternately formed along a direction from the cathode 11 to the anode 12. The thickness of the region 713b is controlled so that surface resistance is 10¹² Ω/sq to 10¹⁵ Ω/sq. The region 713a and the region 713b are metal films made of the same material.

FIG. 8 is a diagram illustrating an insulator 801 according to a second modification. Similarly to the insulator 1 according to Embodiment 1, the insulator 801 according to the second modification includes an insulation member 810, the cathode 11, the anode 12, and a metal film 813 formed on an outer circumferential surface of the insulation member 810. No groove is formed on the outer circumferential surface of the insulator 801 according to the second modification. The metal film 813 of the insulator 801 according to the second modification includes a first metal film 813a controlled to have surface resistance lower than 10¹² Ω/sq to 10¹⁵ Ω/sq, and a second metal film 813b controlled to have surface resistance of 10¹² Ω/sq to 10¹⁵ Ω/sq. In the second modification, for example, the first metal film 813a is made of a metal material selected from titanium nitride, chromium, and chromium oxide, and the second metal film 813b is made of a metal material different from that of the first metal film 813a.

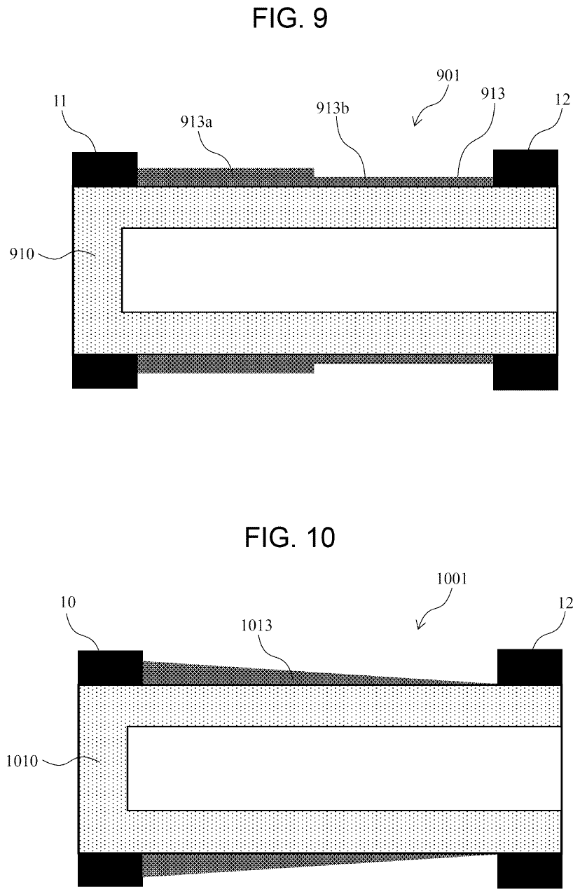

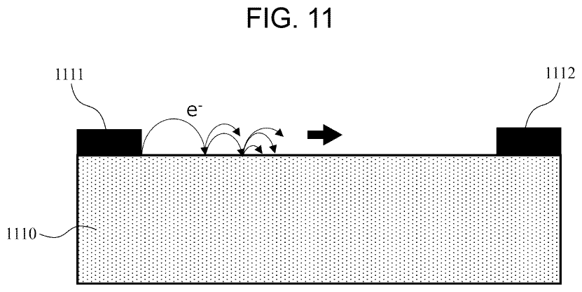

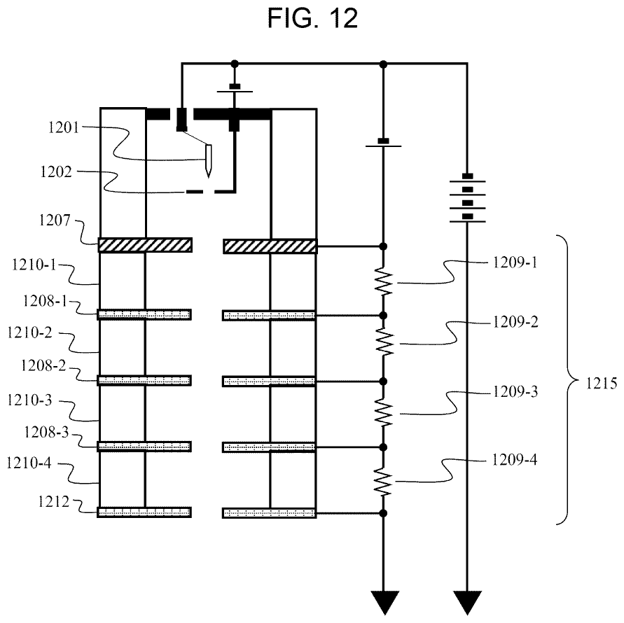

FIG. 9 is a diagram illustrating an insulator 901 according to a third modification. Similarly to the insulator 1 according to Embodiment 1, the insulator 901 according to the third modification includes an insulation member 910, the cathode 11, the anode 12, and a metal film 913 formed on an outer circumferential surface of the insulation member 910. No groove is formed on the outer circumferential surface of the insulator 901 according to the third modification. Only one region 913a having a large thickness and one region 913b having a small thickness of the metal film 913 are formed. The thickness of the region 913b is controlled so that surface resistance is 10¹² Ω/sq to 10¹⁵ Ω/sq.

FIG. 10 is a diagram illustrating an insulator 1001 according to a fourth modification. Similarly to the insulator 1 according to Embodiment 1, the insulator 1001 according to the fourth modification includes an insulation member 1010, the cathode 11, the anode 12, and a metal film 1013 formed on an outer circumferential surface of the insulation member 1010. No groove is formed on the outer circumferential surface of the insulator 1001 according to the fourth modification. The metal film 1013 according to the fourth modification is formed so that its thickness changes linearly. In the fourth modification, a thickness of the metal film 1013 gradually decreases from the cathode 11 toward the anode 12, but the thickness may gradually increase. In a region where the thickness is small, the surface resistance is controlled to be 10¹² Ω/sq to 10¹⁵ Ω/sq.

In the above-described embodiment, the metal film 13 is formed by the DC magnetron sputtering method, but a method for forming the metal film 13 is not limited to the DC magnetron sputtering method, and other sputtering methods or vapor deposition methods may be used.

### REFERENCE SIGNS LIST

1, 701, 801, 901, 1001: insulator
10, 210, 710, 810, 910, 1010: insulation member
10a: hollow
10b, 210b: groove
10c: surface
10d: sloped surface
10e: bottom surface
11: cathode
12: anode
13, 13a, 13b, 13c, 713, 813, 913, 1013: metal film
500: electron gun
501: electron source
502: extraction electrode
503: electron gun column
504: high-voltage connector
510: cable
600: charged particle beam apparatus
601: convergence lens
602: blanking deflector
603: aperture plate
604: image shift deflector
605: objective lens
606: stage
607: detector
608: blanking voltage application device
609: blanking voltage control device
610: convergence lens control device
611: computer system
612: electron beam
613: sample
614: secondary electron
713a, 913a: region having large thickness
713b, 913b: region having small thickness
813a: first metal film
813b: second metal film

1.-14. (canceled)

15. An insulator comprising:
an insulation member;
a first electrode and a second electrode that are provided on the insulation member; and
a metal film that is provided on a surface of the insulation member, wherein
the metal film includes, between the first electrode and the second electrode, one or more first regions with surface resistance of 10¹² Ω/sq to 10¹⁵ Ω/sq, and one or more second regions with surface resistance smaller than the surface resistance of the first regions, and
the first region and the second region are alternately provided along a direction from the first electrode toward the second electrode.

16. The insulator according to claim 15, wherein
the first region and the second region are metal films made of a same material, and
a thickness of the first region is smaller than a thickness of the second region.

17. The insulator according to claim 16, wherein
one or more annular grooves are formed on the surface of the insulation member, and
the first region is formed on a sloped surface constituting the groove, and the second region is formed on a bottom surface or the surface constituting the groove.

18. The insulator according to claim 17, wherein
a height of a sloped surface on a second electrode side constituting the groove is larger than a height of a sloped surface on a first electrode side constituting the groove.

19. The insulator according to claim 17, wherein
the sloped surface is inclined by 0° to 45° with respect to a perpendicular to the surface.

20. The insulator according to claim 15, wherein
the first region and the second region are metal films made of different materials.

21. The insulator according to claim 15, wherein
the metal film is a metal film whose thickness gradually decreases or increases along the direction from the first electrode toward the second electrode, and has surface resistance of 10¹² Ω/sq to 10¹⁵ Ω/sq in a region where the thickness is small.

22. The insulator according to claim 15, wherein
the metal film is made of titanium nitride, chromium, or chromium oxide.

23. A charged particle gun comprising:
the insulator according to claim 15;
a charged particle source; and
an extraction electrode connected to the first electrode or the second electrode of the insulator and configured to extract a charged particle beam from the charged particle source.

24. A charged particle beam apparatus comprising:
the charged particle gun according to claim 23.

25. A method for producing an insulator, the method comprising:
preparing an insulation member;
providing a first electrode and a second electrode on the insulation member; and
alternately providing one or more first regions with surface resistance of 10¹² Ω/sq to 10¹⁵ Ω/sq and one or more second regions with surface resistance smaller than the surface resistance of the first regions along a direction from the first electrode to the second electrode.

26. The method for producing an insulator according to claim 25, wherein
one or more grooves are formed on a surface of the insulation member, and
the alternately providing the first region and the second region includes forming the first region on a sloped surface constituting the groove and forming the second region on a bottom surface constituting the groove using a DC magnetron sputtering method.
